(19) United States
(12) Patent Application Publication
(10) Pub. No.: US 2016/0120027 A1
(43) Pub. Date: Apr. 28, 2016

(54) MULTILAYER CERAMIC ELECTRONIC COMPONENT AND BOARD HAVING THE SAME

(71) Applicant: SAMSUNG ELECTRO-MECHANICS CO., LTD., Suwon-si (KR)

(72) Inventors: Heung Kil PARK, Suwon-Si (KR); Young Ghyu AHN, Suwon-Si (KR); Sang Soo PARK, Suwon-Si (KR); Soon Ju LEE, Suwon-Si (KR); Kyoung Jin JUN, Suwon-Si (KR); So Yeon SONG, Suwon-Si (KR)

(21) Appl. No.: 14/664,786

(22) Filed: Mar. 20, 2015

(30) Foreign Application Priority Data
Oct. 23, 2014 (KR) 10-2014-0144354

(51) Int. Cl. H05K 1/02; H01G 4/12; H05K 1/18; H01G 4/30

(52) U.S. Cl. CPC H05K 1/0271; H01G 4/30; H01G 4/12; H05K 1/181; H05K 2201/10015

(57) ABSTRACT

A multilayer ceramic electronic component including: a multilayer ceramic capacitor (MLCC) including first and second external electrodes extended from both side surfaces of the ceramic body in a width direction of the ceramic body onto portions of a mounting surface of the multilayer cermic capacitor, respectively; and an interposer substrate on which the first and second external electrodes are mounted, and having an elongated groove formed in a length direction of the interposer substrate intersecting the first and second external electrodes.

### CROSS-REFERENCE TO RELATED APPLICATION

This application claims the priority and benefit of Korean Patent Application No. 10-2014-0144354 filed on Oct. 23, 2014, with the Korean Intellectual Property Office, the disclosure of which is incorporated herein by reference.

### BACKGROUND

The present inventive concept relates to a multilayer ceramic electronic component and a board having the same.

Capacitors, inductors, piezoelectric elements, varistors, thermistors, and the like, are representative electronic components using a ceramic material.

Among such ceramic electronic components, a multilayer ceramic capacitor (MLCC) is commonly used in a wide range of electronic apparatuses due to inherent advantages thereof, such as a relatively small size, relatively high capacitance, and an ease in the mounting thereof.

For example, such a multilayer ceramic capacitor may be used as a chip-type condenser mounted on the boards of various electronic products such as image display devices, including liquid crystal displays (LCDs), plasma display panels (PDPs), and the like, as well as computers, personal digital assistants (PDA), and mobile phones, serving to charge electricity therein or discharge electricity therefrom.

Such a multilayer ceramic capacitor may have a structure in which a plurality of dielectric layers and internal electrodes having opposing polarities are alternatingly disposed with respective dielectric layers alternatingly interposed therebetween.

In this case, since the dielectric layer has piezoelectric characteristics, when a direct current (DC) voltage or an alternating current (AC) voltage is applied to such a multilayer ceramic capacitor, a piezoelectric phenomenon may be generated between the internal electrodes, thereby generating periodic vibrations, while expanding and contracting a volume of a ceramic body according to the frequency of the voltage applied thereto.

These vibrations may be transferred to the board through external electrodes of the multilayer ceramic capacitor and solders connecting the external electrodes and the board to each other, such that the entire board is used as a sound reflecting surface generating vibrational sound, commonly known as noise.

Such vibrational sound may correspond to noise within an audio frequency range of 20 to 20,000 hertz (Hz), sound which may cause discomfort to listeners thereof. Vibrational sound causing listener discomfort, as described above, may be termed acoustic noise.

In addition, recently, noiseless mode components have been provided in electronic equipment, such that acoustic noise, such as that generated by multilayer ceramic capacitors as described above, may appear more frequently.

When equipment is operated in an otherwise noiseless environment, users may perceive such acoustic noise as equipment failure.

In addition, in equipment having voice circuits, such acoustic noise overlaps voice outputs, thereby causing an issue of the deterioration of equipment quality.

### SUMMARY

An aspect of the present inventive concept may provide a multilayer ceramic electronic component in which an amount of acoustic noise is reduced and a board having the same.

According to an aspect of the present inventive concept, a multilayer ceramic electronic component may include: a multilayer ceramic capacitor (MLCC) including first and second external electrodes extended from both side surfaces of the ceramic body in a width direction of the ceramic body onto portions of a mounting surface of the multilayer ceramic capacitor, respectively; and an interposer substrate bonded to the mounting surface of the multilayer ceramic capacitor, and having an elongated groove formed in a length direction of the ceramic body intersecting the first and second external electrodes.

According to another aspect of the present inventive concept, a board having a multilayer ceramic electronic component may include: a circuit board on which a plurality of electrode pads are disposed; and the multilayer ceramic electronic component as described above mounted on the circuit board so that terminal electrodes are bonded to the electrode pads, respectively.

### BRIEF DESCRIPTION OF DRAWINGS

The above and other aspects, features and other advantages of the present inventive concept will be more clearly understood from the following detailed description taken in conjunction with the accompanying drawings, in which:

FIG. 1 is a perspective view schematically illustrating a multilayer ceramic electronic component according to an exemplary embodiment in the present inventive concept;

FIG. 2 is an exploded perspective view illustrating a multilayer ceramic capacitor (MLCC) and an interposer substrate of FIG. 1 which are separated from each other;

FIG. 3 is a cross-sectional view of FIG. 1 taken along line A-A′;

FIG. 4 is an exploded perspective view illustrating an example of a structure in which dielectric layers and first and second internal electrodes are stacked in the multilayer ceramic electronic component of FIG. 1;

FIG. 5 is a plan view of the interposer substrate of the multilayer ceramic electronic component of FIG. 1;

FIG. 6 is a perspective view illustrating another example of an interposer substrate of a multilayer ceramic electronic component according to an exemplary embodiment in the present inventive concept; and

FIG. 7 is a cross-sectional view illustrating the multilayer ceramic electronic component of FIG. 1 mounted on a circuit board.

### DETAILED DESCRIPTION

Exemplary embodiments in the present inventive concept will now be described in detail with reference to the accompanying drawings.

The inventive concept may, however, be exemplified in many different forms and should not be construed as being limited to the specific embodiments set forth herein. Rather, these embodiments are provided so that this disclosure will be thorough and complete, and will fully convey the scope of the inventive concept to those skilled in the art.

In the drawings, the shapes and dimensions of elements may be exaggerated for clarity, and the same reference numerals will be used throughout to designate the same or like elements.

As used herein, it will be further understood that the terms “include” and/or “have” when used in the present inventive concept, specify the presence of elements, but do not preclude the presence or addition of one or more other elements, unless otherwise indicated.

### Multilayer Ceramic Electronic Component

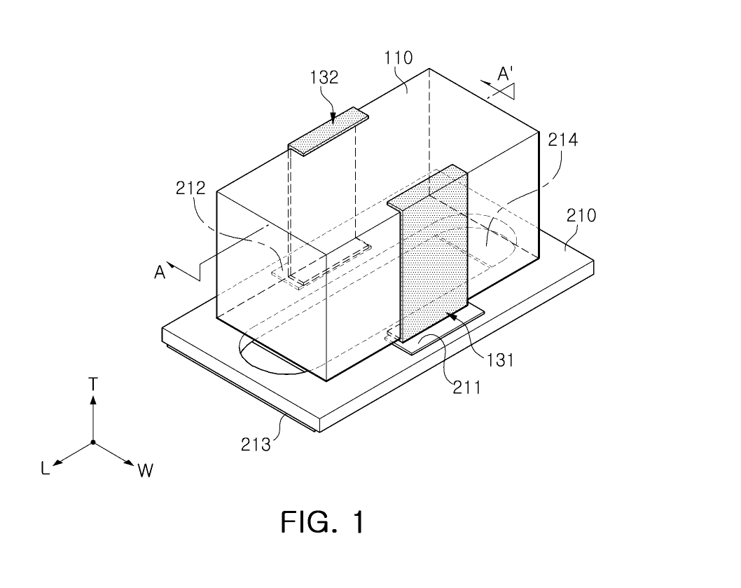

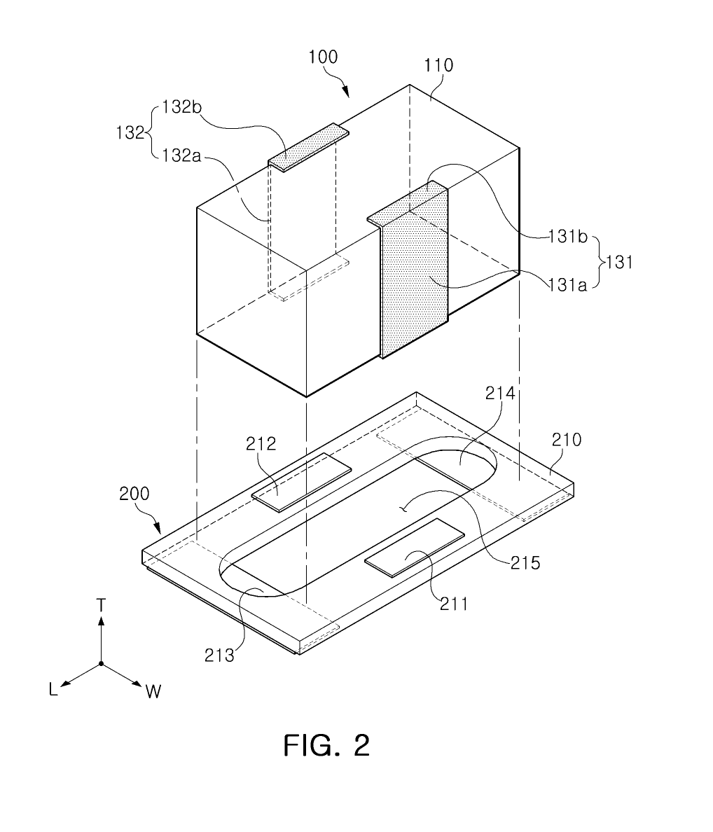

FIG. 1 is a perspective view schematically illustrating a multilayer ceramic electronic component according to an exemplary embodiment in the present inventive concept; FIG. 2 is an exploded perspective view illustrating a multilayer ceramic capacitor (MLCC) and an interposer substrate of FIG.

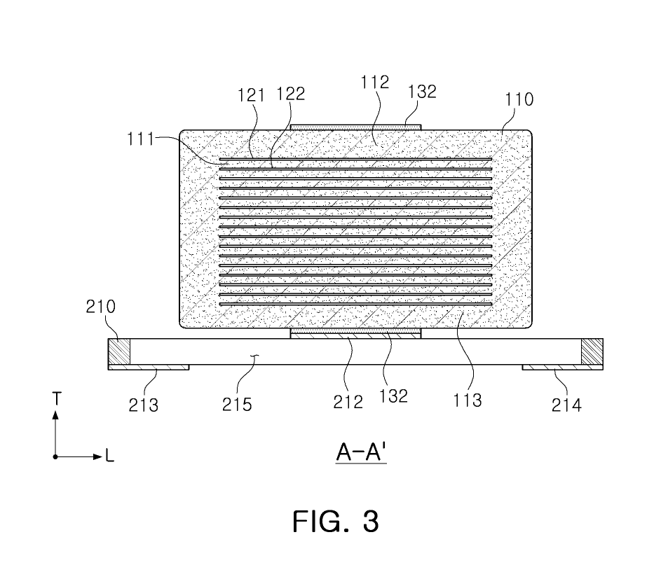

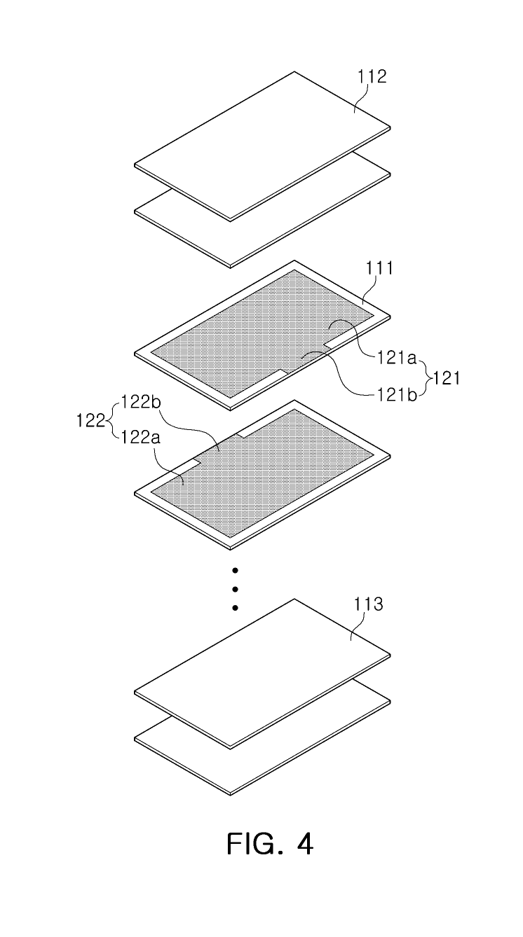

which are separated from each other; FIG. 3 is a cross-sectional view of FIG. 1 taken along line A-A′; and FIG. 4 is an exploded perspective view illustrating one example of a structure in which dielectric layers and first and second internal electrodes are stacked in the multilayer ceramic electronic component of FIG. 1.

Referring to FIGS. 1 through 4, the multilayer ceramic electronic component according to the present exemplary embodiment may include a multilayer ceramic capacitor 100 and an interposer substrate 200.

As used herein, the interposer substrate refers to a sheet shaped member or a plate shaped member enabling a fan-out or pad pitch expansion. The interposer substrate may be formed of a resin material such as flame retardant 4 (FR4). However, the type of material forming the interposer substrate is not limited thereto.

That is, the interposer substrate may practically refer to a substrate for changing a pitch of an electrode terminal used at the time of mounting an electronic component on a circuit board. The electronic component and the circuit board may be electrically connected to each other by the interposer substrate as described above.

The multilayer ceramic capacitor 100 may include a ceramic body 110; and first and second internal electrodes 121 and 122; and first and second external electrodes 131 and 132.

The ceramic body 110 may be formed by stacking a plurality of dielectric layers 111 in a thickness direction T of the ceramic body 110 and performing a sintering process.

Here, adjacent dielectric layers 111 of the ceramic body 110 may be integrated with each other so that boundaries therebetween are indiscernible.

In addition, the ceramic body 110 may have a hexahedral shape. However, the shape of the ceramic body is not limited thereto.

In the present exemplary embodiment, for ease of description, surfaces of the ceramic body 110 opposing each other in a thickness direction T of the ceramic body 110 in which the dielectric layers 111 of the ceramic body 110 are stacked are referred to as lower and upper surfaces of the ceramic body 110, respectively, surfaces of the ceramic body 110 connecting the upper and lower surfaces and opposing each other in a length direction L of the ceramic body 110 are referred to as first and second end surfaces of the ceramic body 110, respectively, and surfaces of the ceramic body 110 vertically intersecting the first and second end surfaces and opposing each other in a width direction W of the ceramic body 110 are referred to as first and second side surfaces of the ceramic body 110, respectively.

Meanwhile, the ceramic body 110 may have an upper cover layer 112 formed above an uppermost internal electrode and a lower cover layer 113 formed below a lowermost internal electrode, wherein the upper cover layer 112 has a predetermined thickness.

Here, the upper and lower cover layers 112 and 113 may be formed of the same composition as that of the dielectric layer 111, and may be formed by stacking at least one dielectric layer not including the internal electrodes above the uppermost internal electrode and below the lowermost internal electrode of the ceramic body 110.

The dielectric layer 111 may contain a high-k ceramic material, for example, barium titanate (BaTiO₃) based ceramic powder, or the like. However, the type of material contained in the dielectric layer 111 is not limited thereto.

An example of the BaTiO₃-based ceramic powder may have (Ba₁₋ₓCaₓ)TiO₃, Ba(Ti_{1-y}Ca_{y})O₃, (Ba₁₋ₓ,Caₓ)(Ti_{1-y}Zr_{y})O₃, Ba(Ti_{1-y}Zr_{y})O₃, and the like, in which calcium (Ca), zirconium (Zr), or the like, is partially dissolved in BaTiO₃. However, the example of the BaTiO₃-based ceramic powder is not limited thereto.

In addition, the dielectric layer 111 may further include at least one of a ceramic additive, an organic solvent, a plasticizer, a binder, and a dispersant.

As the ceramic additive, for example, a transition metal oxide or carbide, a rare earth element, magnesium (Mg), aluminum (Al), or the like, may be used.

The first and second internal electrodes 121 and 122 may be formed on ceramic sheets forming the dielectric layers 111 to be stacked thereon, and then may be sintered, such that they are alternatingly disposed in the ceramic body 110 with each of the dielectric layers 111 interposed therebetween.

The first and second internal electrodes 121 and 122 having opposing polarities may be disposed to face each other in a direction in which the dielectric layers 111 are stacked and may be electrically insulated from each other by the dielectric layers 111 disposed therebetween.

The first and second internal electrodes 121 and 122 may be exposed through the first and second side surfaces of the ceramic body 110 in the width direction of the ceramic body 110, respectively.

Here, the first and second internal electrodes 121 and 122 may include first and second body parts 121a and 122a vertically overlapping each other, respectively, and first and second lead parts 121b and 122b extended from the first and second body parts 121a and 122a in the width direction of the ceramic body 110, respectively, to be exposed through the first and second side surfaces of the ceramic body 110 in the width direction of the ceramic body 110, respectively.

In addition, the first and second internal electrodes 121 and 122 may be formed of a conductive material, for example, a material such as nickel (Ni), a Ni alloy, or the like. However, the type of material forming the first and second internal electrodes 121 and 122 is not limited thereto.

The first and second external electrodes 131 and 132 may be extended from the first and second side surfaces of the ceramic body 110 in the width direction of the ceramic body 110 onto portions of the lower surface of the ceramic body 110 which is a mounting surface of the ceramic body 110, respectively.

In addition, the first and second external electrodes 131 and 132 may be disposed to be spaced apart from the first and second end surfaces of the ceramic body 110 in the length direction of the ceramic body 110, and for example, may be positioned in a center of the ceramic body 110 in the length direction of the ceramic body 110 to face each other in the width direction of the ceramic body 110.

When the first and second external electrodes 131 and 132 are disposed to be spaced apart from the first and second end surfaces of the ceramic body 110 in the length direction of the ceramic body 110 as described above, the first and second external electrodes 131 and 132 may come into contact with surfaces having a least amount of displacement generated in the ceramic body 110, such that vibrations generated from the ceramic body 110 and transferred through the first and second external electrodes 131 and 132 may be reduced by an amount equal to the least amount of displacement generated in the ceramic body 110.

Here, the first and second lead parts 121b and 122b of the first and second internal electrodes 121 and 122 exposed through the first and second side surfaces of the ceramic body 110 in the width direction of the ceramic body 110 may be electrically connected to the first and second external electrodes 131 and 132, respectively.

In addition, the first and second external electrodes 131 and 132 may be extended from the first and second side surfaces of the ceramic body 110 in the width direction of the ceramic body 110 onto portions of the upper surface of the ceramic body 110 which is a surface of the ceramic body 110 opposing the mounting surface of the ceramic body 110, respectively. In this case, sticking strength of the first and second external electrodes 131 and 132 may be increased.

In addition, as necessary, the first and second external electrodes 131 and 132 may have plating layers (not illustrated) formed thereon. By way of example, the plating layers may include first and second Ni plating layers formed on the first and second external electrodes 131 and 132, respectively, and first and second tin (Sn) plating layers formed on the first and second Ni plating layers, respectively.

According to the configuration as described above, when predetermined voltages are applied to the first and second external electrodes 131 and 132, electric charges may be accumulated between the first and second internal electrodes 121 and 122 facing each other.

Here, a level of capacitance of the multilayer ceramic capacitor 100 may be in proportion to an overlapping area of the first and second body parts 121a and 122a of the first and second internal electrodes 121 and 122 which are overlapping each other in the direction in which the dielectric layers 111 are stacked.

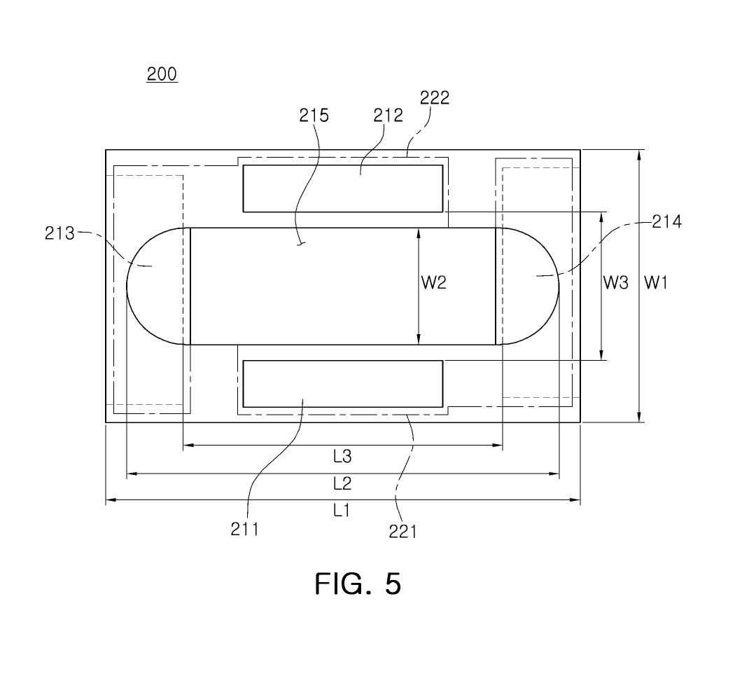

FIG. 5 is a plan view of the interposer substrate of the multilayer ceramic electronic component of FIG. 1.

Referring to FIG. 5, in the interposer substrate 200 included in the multilayer ceramic electronic component of the present exemplary embodiment, an insulating substrate may be vertically cut into portions to have a predetermined size thereof, and an elongated groove 215 may be formed in the cut insulating substrate 210 in a length direction of the insulating substrate 200. Here, the elongated groove 215 may be a through-groove. However, the present inventive concept is not limited thereto.

In addition, first and second electrode patterns 211 and 212 may be formed on an upper surface of the insulating substrate 210 to face each other, with the elongated groove 215 interposed therebetween in a width direction of the insulating substrate 210, and first and second connection terminals 213 and 214 facing each other in the length direction of the insulating substrate 210 may be formed on a lower surface of the insulating substrate 210, with the elongated groove 215 interposed therebetween.

Here, the first and second electrode patterns 211 and 212 may be bonded and electrically connected to lower surfaces of the first and second external electrodes 131 and 132 of the multilayer ceramic capacitor 100, respectively.

The first and second electrode patterns 211 and 212 may be formed by printing conductive layers onto portions of an upper surface of the insulating substrate 210 opposing each other in the width direction of the insulating substrate 210 with the elongated groove 215 interposed therebetween. The remainder of the upper surface of the insulating substrate 210 aside from portions of the upper surface of the insulating substrate 210 on which the first and second electrode patterns 211 and 212 are to be formed may be covered with a resist such as a resin to thereby generate solder resist openings (SROs) in the insulating substrate 210 to form the first and second electrode patterns 211 and 212 that are exposed.

The first and second external electrodes 131 and 132 and the first and second electrode patterns 211 and 212 may be bonded to each other by a conductive adhesive. Here, the conductive adhesive may be a solder or a conductive paste. However, the type of bonding material is not limited thereto.

Further, the first and second electrodes patterns 211 and 212 may have plating layers formed thereon by performing a Ni plating process or a gold (Au) plating process on surfaces of the first and second electrodes patterns 211 and 212, as necessary.

The first and second connection terminals 213 and 214 may be formed by printing conductive layers onto portions of a lower surface of the insulating substrate 210 opposing each other in the length direction of the insulating substrate 210 with the elongated groove 215 interposed therebetween. The remainder of the lower surface of the insulating substrate 210 aside from portions of the lower surface of the insulating substrate 210 on which the first and second connection terminals 213 and 214 are to be formed may be covered with a resist such as a resin to thereby generate SROs in the insulating substrate 210 to form the first and second connection terminals 213 and 214 that are exposed.

Here, the first and second connection terminals 213 and 214 may have plating layers formed thereon by performing a Ni plating process or a Au plating process on surfaces of the first and second connection terminals 213 and 214, as necessary.

The interposer substrate 200 may serve to absorb and alleviate stress or vibrations occurring due to a piezoelectric property of the multilayer ceramic capacitor 100 through the insulating substrate 210, such that the level of acoustic noise generated in the board is mounted may be reduced.

In addition, according to the present exemplary embodiment, a contact area between the lower surface of the ceramic body 110 and the insulating substrate 210 of the interposer substrate 200 may be decreased due to the elongated groove 215. Accordingly, in proportion to the decreased contact area therebetween, an amount of vibrations transferred from the ceramic body 110 to the insulating substrate 210 of the interposer substrate 200 may be reduced, whereby an amount of acoustic noise may be reduced.

In addition, since the interposer substrate 200 absorbs external mechanical stress and bending of the board, occurrence of cracks, and the like, in the multilayer ceramic capacitor 100 may be decreased.

Here, when a length of the insulating substrate 210 is L1, a length of the elongated groove 215 is L2, and a distance between the first and second connection terminals 213 and 214 is L3, L3<L2<L1 may be satisfied.

When the multilayer ceramic electronic component is mounted on the board, solders need climb upward along the interposer substrate 200 to be connected to the multilayer ceramic capacitor. However, when the length L2 of the elongated groove 215 is the same as or smaller than the distance L3 between the first and second connection terminals 213 and 214, the solders formed through a wall of the elongated groove 215 may not be in contact with the first and second external electrodes 131 and 132, such that the first and second electrode patterns 211 and 212 may not be electrically connected to the first and second connection terminals 213 and 214.

Further, when a width of the insulating substrate 210 is W1, a width of the elongated groove 215 is W2, and a distance between the first and second electrode patterns 211 and 212 is W3, W2≦W3 may be satisfied. Here, when W2 is greater than W3, the contact area between the multilayer ceramic capacitor and the interposer substrate may be excessively decreased, whereby sticking strength thereof may be deteriorated.

### MODIFIED EXAMPLE

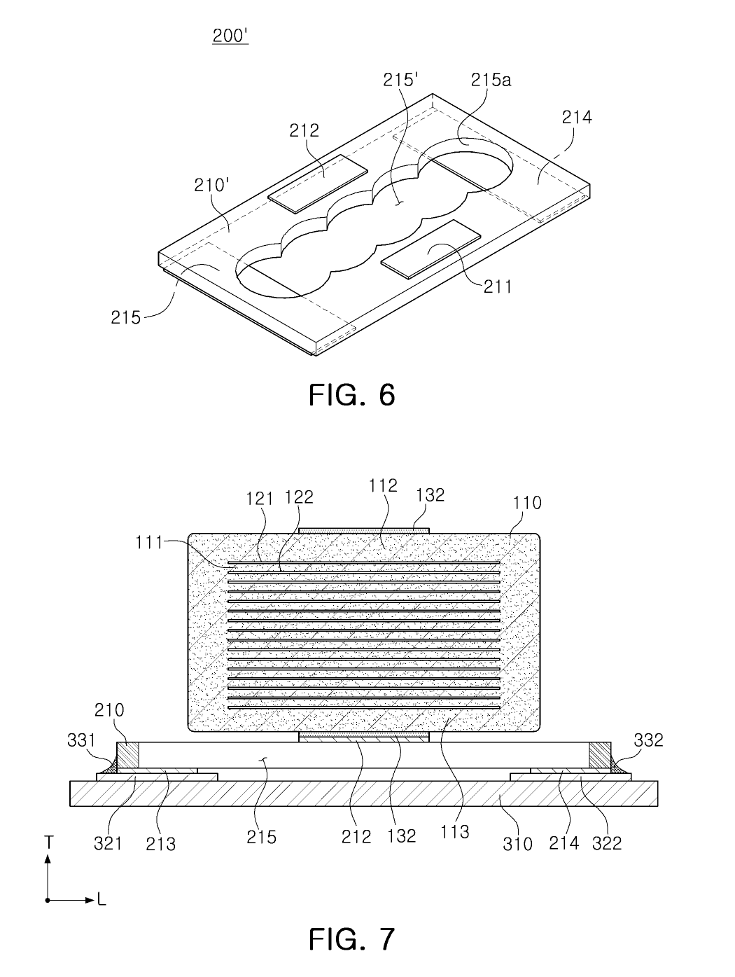

FIG. 6 is a perspective view illustrating another example of an interposer substrate in a multilayer ceramic electronic component according to the present inventive concept.

Here, since structures of an insulating substrate 210′, first and second electrode patterns 211 and 212, and first and second connection terminals 213 and 214 of an interposer substrate 200′ are similar to those described in the previously described exemplary embodiment, detailed descriptions thereof will be omitted in order to avoid repetition, and a structure changed from the previously exemplary embodiment will be described in detail.

Referring to FIG. 6, in the interposer substrate 200′ of the present exemplary embodiment, an elongated groove 215′ formed within the insulating substrate 210′ in a length direction of the insulating substrate 210′ may have an inner peripheral surface 215a having a concavo-convex shape.

Such a concavo-convex shape may be formed by operating a circular punch several times while moving in the length direction of the insulating substrate 210′ of the interposer substrate 200′. Accordingly, the elongated groove 215′ may be easily formed.

Here, a size of a concavo-convex of the inner peripheral surface 215a of the elongated groove 215′ may be controlled by adjusting an interval between punching operations by the circular punch. The inner peripheral surface 215a of the elongated groove 215′ may function to control a flow of a melting solder and control aggregation and spreading of the melting solder, such that an amount of the melting solder may be controlled by adjusting the size of the concavo-convex of the inner peripheral surface 215a of the elongated groove 215′.

### Board Having Multilayer Ceramic Electronic Component

FIG. 7 is a cross-sectional view illustrating the multilayer ceramic electronic component of FIG. 1 mounted on the circuit board.

Referring to FIG. 7, the board having the multilayer ceramic electronic component according to the exemplary embodiment in the present inventive concept may include a circuit board 310 on which the multilayer ceramic capacitor 100 is horizontally mounted and first and second electrode pads 321 and 322 formed on the circuit board 310 to be spaced apart from each other.

Here, the multilayer ceramic electronic component may be electrically connected to the circuit board 310 by solders 331 and 332, and the like, in a state in which the first and second connection terminals 213 and 214 are positioned on the first and second electrode pads 321 and 322 to be in contact with each other, respectively.

When a voltage is applied in a state in which the multilayer ceramic electronic component is mounted on the circuit board 310 as described above, acoustic noise may occur.

Here, a size of the first and second electrode pads 321 and 322 may be an indicator determining an amount of the solders 331 and 332 connecting the first and second connection terminals 213 and 214 and the first and second electrode pads 321 and 322 of the multilayer ceramic electronic component to each other, and a level of the acoustic noise may be controlled based on the amount of the solders 331 and 332.

According to the present exemplary embodiment, when voltages having opposing polarities are applied to the first and second external electrodes 131 and 132 formed on the first and second side surfaces of the ceramic body 110 in the length direction of the ceramic body 110 in a state in which the multilayer ceramic electronic component is mounted on the circuit board 310, the ceramic body 100 may be expanded and contracted in the thickness direction of the ceramic body 110 due to an inverse piezoelectric effect of the dielectric layers 111, and the first and second end surfaces of the ceramic body 110 in the length direction of the ceramic body 110 on which the first and second external electrodes 131 and 132 are formed maybe contracted and expanded, as opposed to the expansion and the contraction of the ceramic body 110 in the thickness direction of the ceramic body 110 due to a Poisson effect.

The interposer substrate 200 may primarily alleviate vibrations transferred from the multilayer ceramic capacitor 100 to thereby reduce acoustic noise of the multilayer ceramic electronic component.

In addition, when external mechanical stress is applied, the interposer substrate 200 may absorb a portion of the stress to prevent the multilayer ceramic capacitor 100 from being mechanically damaged.

Here, according to the present exemplary embodiment, the contact area between the insulating substrate 210 of the interposer substrate 200 and the ceramic body 110 may be decreased due to the elongated groove 215 formed in the interposer substrate 200, such that acoustic noise transferred to the circuit board 310 through the ceramic body 110 and the first and second external electrodes 131 and 132 of the multilayer ceramic capacitor 100 may be effectively reduced.

In addition, the elongated groove 215 may electrically connect the first and second electrode patterns 211 and 212 and the first and second connection terminals 213 and 214 to each other.

As set forth above, according to exemplary embodiments of the present inventive concept, the contact area between the interposer substrate and the ceramic body may be decreased due to the elongated groove formed in the interposer substrate, such that acoustic noise transferred to the board through the ceramic body and the external electrodes of the multilayer ceramic capacitor may be reduced.

While exemplary embodiments have been shown and described above, it will be apparent to those skilled in the art that modifications and variations could be made without departing from the scope of the invention as defined by the appended claims.

What is claimed is:

1. A multilayer ceramic electronic component comprising:
a multilayer ceramic capacitor (MLCC) including first and second external electrodes extended from both side surfaces of the ceramic body in a width direction of the ceramic body onto portions of a mounting surface of the multilayer ceramic capacitor, respectively; and
an interposer substrate on which the first and second external electrodes are mounted, and having an elongated groove formed in a length direction of the interposer substrate intersecting the first and second external electrodes.

2. The multilayer ceramic electronic component of claim 1, wherein in the interposer substrate, the elongated groove has an inner peripheral surface having a concavo-convex shape.

3. The multilayer ceramic electronic component of claim 1, wherein in the interposer substrate, first and second connection terminals are disposed at both ends of the interposer substrate in the length direction of the interposer substrate on a surface of the interposer substrate opposing a surface of the interposer substrate on which the multilayer ceramic capacitor is mounted, and when a length of the interposer substrate is L1, a length of the elongated groove is L2, and a distance between the first and second connection terminals is L3, L3<L2<L1 is satisfied.

4. The multilayer ceramic electronic component of claim 1, wherein in the interposer substrate, first and second electrode patterns are disposed on the surface of the interposer substrate on which the multilayer ceramic capacitor is mounted to be adjacent to both side surfaces of the interposer substrate in the width direction of the interposer substrate, and when a width of the elongated groove is W2, and a distance between the first and second electrode terminals is W3, W2≦W3 is satisfied.

5. The multilayer ceramic electronic component of claim 1, wherein in the multilayer ceramic capacitor, the first and second external electrodes are disposed to be spaced apart from both end surfaces of the ceramic body in the length direction of the ceramic body.

6. The multilayer ceramic electronic component of claim 5, wherein the first and second external electrode are positioned in a center of the ceramic body in the length direction of the ceramic body.

7. The multilayer ceramic electronic component of claim 1, wherein in the multilayer ceramic capacitor, the first and second external electrodes are extended from both side surfaces of the ceramic body in the width direction of the ceramic body onto portions of a surface of the multilayer ceramic capacitor opposing the mounting surface of the multilayer ceramic capacitor, respectively.

8. A multilayer ceramic electronic component comprising:
a multilayer ceramic capacitor (MLCC) including a ceramic body including a plurality of dielectric layers stacked therein; a plurality of first and second internal electrodes disposed to be alternatingly exposed through both side surfaces of the ceramic body in a width direction of the ceramic body, with each of the dielectric layers interposed therebetween, and first and second external electrodes extended from both side surfaces of the ceramic body in the width direction of the ceramic body onto portions of a mounting surface of the multilayer ceramic capacitor, respectively, and each connected to the first and second internal electrodes; and
an interposer substrate including an insulating substrate having an elongated groove in a length direction of the interposer substrate, first and second electrode patterns disposed to face each other in a width direction of the interposer substrate on an upper surface of the insulating substrate to be bonded to the first and second external electrodes, respectively, and first and second connection terminals disposed to face each other in a length direction of the interposer substrate on a lower surface of the insulating substrate.

9. The multilayer ceramic electronic component of claim 8, wherein in the interposer substrate, the elongated groove of the insulating substrate has an inner peripheral surface having a concavo-convex shape.

10. The multilayer ceramic electronic component of claim 8, wherein in the interposer substrate, the first and second connection terminals are disposed at both ends of the interposer substrate in the length direction of the interposer substrate on a surface of the interposer opposing a surface of the interposer substrate on which the multilayer ceramic capacitor is mounted, and when a length of the insulating substrate is L1, a length of the elongated groove is L2, and a distance between the first and second connection terminals is L3, L3<L2<L1 is satisfied.

11. The multilayer ceramic electronic component of claim 8, wherein in the interposer substrate, the first and second electrode patterns are disposed on the surface of the interposer substrate on which the multilayer ceramic capacitor is mounted to be adjacent to both side surfaces of the interposer substrate in the width direction of the interposer substrate, respectively, and when a width of the elongated groove is W2, and a distance between the first and second electrode terminals is W3, W2≦W3 is satisfied.

12. The multilayer ceramic electronic component of claim 8, wherein in the multilayer ceramic capacitor, the first and second external electrodes are disposed to be spaced apart from both end surfaces of the ceramic body in the length direction of the ceramic body.

13. The multilayer ceramic electronic component of claim 12, wherein the first and second external electrodes are positioned in a center of the ceramic body in the length direction of the ceramic body.

14. The multilayer ceramic electronic component of claim 8, wherein in the multilayer ceramic capacitor, the first and second external electrodes are extended from both side surfaces of the ceramic body in the width direction of the ceramic body onto portions of a surface of the ceramic body opposing the mounting surface of the multilayer ceramic capacitor, respectively.

15. The multilayer ceramic electronic component of claim 8, wherein in the multilayer ceramic capacitor, the first and second internal electrodes include first and second body parts overlapping each other; and first and second lead parts extended from the first and second body parts to be exposed through both side surfaces of the ceramic body in the width direction of the ceramic body, respectively.

16. The multilayer ceramic electronic component of claim 8, wherein in the multilayer ceramic capacitor, the ceramic body further includes cover layers disposed above an uppermost internal electrode and below a lowermost internal electrode, respectively.

17. A board having a multilayer ceramic electronic component, comprising:
a circuit board on which a plurality of electrode pads are disposed; and
the multilayer ceramic electronic component of claim 1 mounted on the circuit board so that terminal electrodes are bonded to the electrode pads, respectively.
